(19) United States
(12) Patent Application Publication
(10) Pub. No.: US 2010/0108980 A1
(43) Pub. Date: May 6, 2010

(54) RESISTIVE MEMORY ARRAY

(75) Inventor: Frederick T. Chen, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/264,225

(22) Filed: Nov. 3, 2008

(51) Int. Cl. H01L 45/00

(52) U.S. Cl. 257/5; 257/E45.002

(57) ABSTRACT

The invention is directed to a resistive memory cell on a substrate. The resistive memory cell comprises a first gate, a second gate, a common doped region, a contact plug, a bit line and a resistive memory element. The first gate and the second gate are separately disposed on the substrate. Notably, the first length of the first gate is different from the second length of the second gate. Furthermore, the common doped region of the first gate and the second gate is disposed in the substrate. The contact plug is electrically connected to the common doped region and the bit line is disposed over the substrate. Moreover, the resistive memory element is connected between the contact plug and the bit line.

### BACKGROUND OF THE INVENTION

1. Field of Invention

The present invention relates to a memory array. More particularly, the present invention relates to a resistive memory array in which each of the resistive memory cells has at least four memory storage states.

2. Description of Related Art

Nonvolatile memory maintains the stored data even when the power supply is removed. Therefore, nonvolatile memory has been widely employed in a computer, a mobile communication system, a memory card and so on. Flash memory is widely used for nonvolatile memory. In flash memory, typically, the memory cells have stacked gate structures respectively. Normally, each of the stacked gate structures includes a tunnel oxide layer, a floating gate, an inter-gate dielectric layer and a control gate electrode, which are all sequentially stacked on a channel region. In order to enhance a reliability and a program efficiency of the flash memory cell, a film quality of the tunnel oxide layer should be improved and the coupling ratio of the flash memory cell should be increased.

Recently, a new nonvolatile memory, such as resistance random access memory (RRAM), is developed for replacing the flash memory. Conventionally, a unit resistive memory cell of the RRAM includes a switching device and a data storage element serially connected to the switching device. Further, the data storage element of the resistive memory cell is made of a variable resistive material whose resistivity changes in response to an electrical signal in a form of electrical current passing through itself. Therefore, by properly controlling the programming current passing through the variable resistive material, the data can be stored in the resistive memory cell in a form of resistance. However, the magnitude of the programming current is determined by an externally set compliance limit which is further determined by the gate voltage of the driving metal-oxide-semiconductor field effect transistor (MOSFET) which is used as the switching device in the resistive memory cell.

### SUMMARY OF THE INVENTION

The invention provides a resistive memory cell on a substrate. The resistive memory cell comprises a first gate, a second gate, a common doped region, a contact plug, a bit line and a resistive memory element. The first gate and the second gate are separately disposed on the substrate. Notably, the first length of the first gate is different from the second length of the second gate. Furthermore, the common doped region of the first gate and the second gate is disposed in the substrate. The contact plug is electrically connected to the common doped region and the bit line is disposed over the substrate. Moreover, the resistive memory element is connected between the contact plug and the bit line.

The present invention also provides a resistive memory array. The resistive memory array comprises a substrate, a plurality of parallel word lines acting as MOSFET gates, a plurality of bit lines and a plurality of resistive memory elements. Parallel word line pairs are located on the substrate and each of the parallel word line pairs comprises a first gate and a second gate parallel to each other The two gates also share a common doped region, e.g., a common drain. A first length of the first gate is different from a second length of the second gate. The bit lines are disposed over the substrate and over the parallel gate pairs. The resistive memory elements are located between the bit lines and the common doped regions respectively and each of the bit lines is electrically connected to each of the common doped regions through one of the resistive memory elements.

In the present invention, because of the unequal lengths of the gates sharing a common doped region, there can be a total of four memory states, which represents the behaviors of two bit of data, for a single resistive memory cell. Thus, the bit density is increased. Furthermore, by controlling the lengths of the gates, the differences between the programming currents of different data storage states is increased and varied without being limited by the applied gate voltages on the gates.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view schematically illustrating a resistive memory array according to one embodiment of the invention.

FIG. 2 is a cross-sectional view along a line I-I in FIG. 1 and showing a resistive memory cell according to one embodiment of the invention.

FIG. 3 is a cross-sectional view showing a resistive memory cell according to another embodiment of the invention.

FIG. 4 is a plot diagram of source-drain current versus gate voltage showing the differences between the voltage modulation operation of the resistive memory cell and the gate length modulation operation of the resistive memory cell.

### DESCRIPTION OF THE PREFERRED EMBODIMENTS

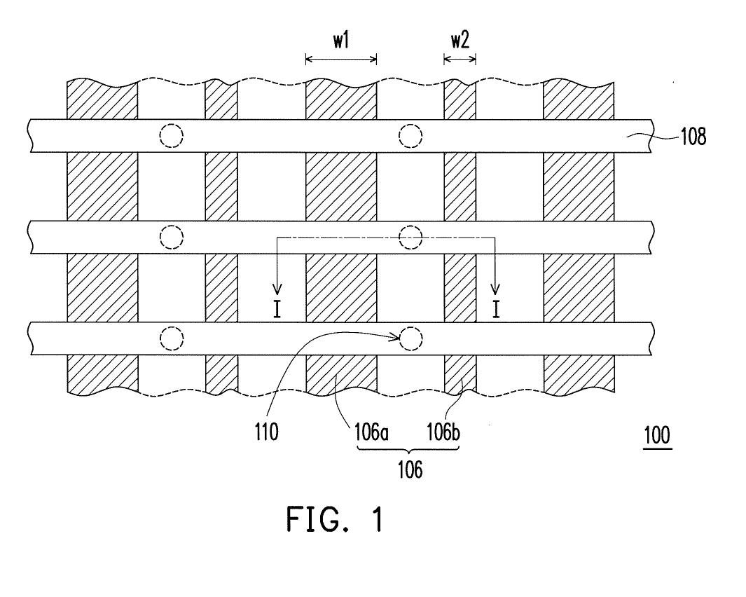

FIG. 1 is a top view schematically illustrating a resistive memory array according to a one embodiment of the invention. As shown in FIG. 1, a substrate 100 is provided. The substrate 100 has a plurality of doped regions 102 (not shown) formed therein, separated by isolation regions (also not shown). The doped regions 102 have conductivity types different from that of the substrate 100.

As shown in FIG. 1, a plurality of parallel gate pairs 106 are located on the substrate 100. Each of the parallel gate pairs 106 comprises a first gate 106a and a second gate 106b parallel to each other. Notably, the first gate and the second gate share one of the doped regions 102 and for each of the parallel gate pairs 106. Moreover, a first length w1 of the first gate 106a is different from a second length w2 of the second gate 106b. It should be noted that, a preferred ratio of the first length w1 to the second length w2 is about 1.5˜9. Furthermore, the first length w1 is about 10˜90 nm and the second length w2 is about 5˜35 nm. In one embodiment of the present invention, the first length w1 is about 33˜72 nm and the second length w2 is about 6˜28 nm. Moreover, in another embodiment, the sum of the first length w1 and the second length w2 is equal to one feature size F which is half of the minimum lithographic pitch. That is, both of the first length w1 and the second length w2 are smaller than the feature size F.

As shown in FIG. 1, for each of the parallel gate pairs 106, there are a first doped region 104a and a second doped region 104b disposed in the substrate 100 and adjacent to the first gate 106a and the second gate 106b respectively and distinct from the common doped region 102 between the first gate 106a and the second gate 106b. In other words, for the resistive memory cells in the same column of the memory array shown in FIG. 1, the doped region 102 can be used, for example, as a common drain region of the first gate 106a and the second gate 106b. Also, the first doped region 104a functions as a source region of the first gate 106a and the second doped region 104b functions as a source region of the second gate 106b. It should be noticed that the conductivity type of the first doped region 104a is different from that of the substrate 100 and the conductivity type of the second doped region 104b is also different from that of the substrate 100. Also, the first doped region 104a and the second doped region 104b can be either grounded or connected to a power rail, for example.

Furthermore, a plurality of bit lines 108 are disposed over the substrate 100 and cross over the parallel gate pairs 106. The material of the bit lines can be, for example, a conductive material such as metal or doped polysilicon. Also, a plurality of resistive memory elements 110 are located between the bit lines 108 and the common doped regions 102 respectively. It should be noted that each of the bit lines 108 is electrically connected to each of the common doped regions 102 through one of the resistive memory elements 110. The material of the resistive memory elements 110 can be a variable-resistance material which exhibits reversible resistance switching according to the applied electrical voltage. That is, the material of the resistive memory elements 110 changes electrical resistance in response to the electrical signal passing primarily through the resistive memory elements 110. The material of the resistive memory elements 110 can be a chalcogenide, a metal oxide, or a perovskite material.

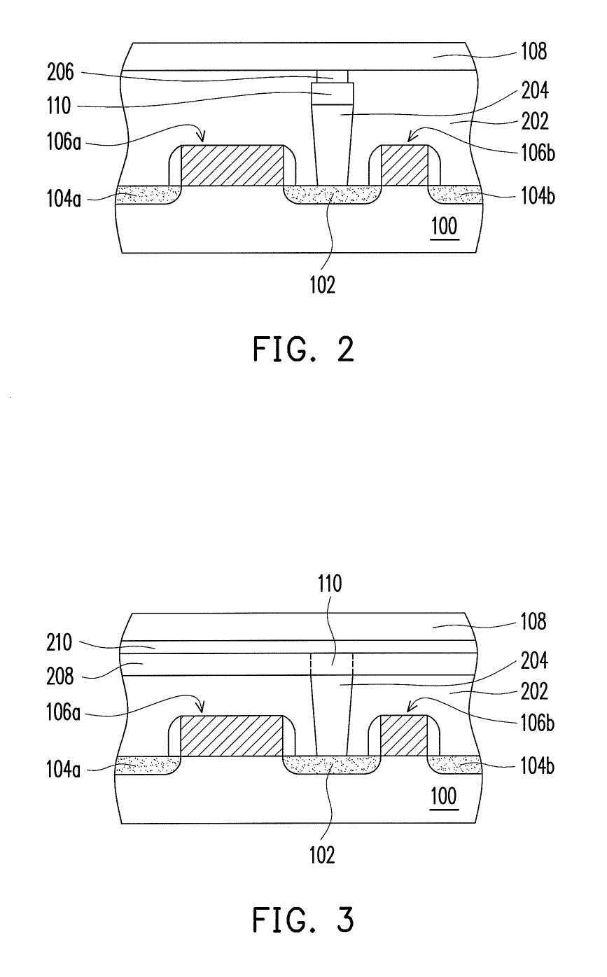

FIG. 2 is a cross-sectional view along a line I-I in FIG. 1 and showing a resistive memory cell according to one embodiment of the invention. The single resistive memory cell is described in detail in the following and the same numerical labels denote the same element in both FIG. 1 and FIG. 2. As shown in FIG. 2, the first gate 106a and the second gate 106b are separately disposed on the substrate 100. As mentioned previously, the first length w1 of the first gate 106a is different from the second length w2 of the second gate 106b.

Then, as shown in FIG. 2, the first gate 106a and the second gate 106b have the common doped region 102 disposed in the substrate 100 between the first gate 106a and the second gate 106b. A contact plug 204 is located on the substrate 100 and is electrically connected to the common doped region 102. Furthermore, the bit line 108 is disposed over the substrate 100 and across the first gate 106a and the second gate 106b. The bit line 108 is isolated from the first gate 106a and the second gate 106b by a dielectric layer 202. Also, the resistive memory element 110 is disposed over the contact plug 204 and the substrate 100 and is connected between the contact plug 204 with the bit line 108.

As shown in FIG. 2, the resistive memory element 110 of the present embodiment is located within the dielectric layer 202. Between the resistive memory element 110 and the bit line 108, there can be a conductive layer 206 used as a top electrode. Also, between the resistive memory element 110 and the contact plug 204, there can be a conductive layer (not shown) used as a bottom electrode. The material of the top electrode 206 can be, for example but not limited to, iridium, platinum, iridium oxide, titanium nitride, titanium aluminum nitride, ruthenium or ruthenium oxide. In one embodiment, the material of the top electrode 206 can be, for example, polysilicon. Furthermore, the material of the bottom electrode (not shown) between the resistive memory element 110 and the contact plug 204 can be, for example but not limited to, iridium, platinum, iridium oxide, titanium nitride, titanium aluminum nitride, ruthenium, ruthenium oxide or polysilicon.

In the embodiment shown in FIG. 2, the resistive memory element is a block type element located between the bit line 108 and the contact plug 204 and above the common doped region 102. However, the present invention is not limited by the form of the resistive memory element. FIG. 3 is a cross-sectional view showing a resistive memory cell according to the other embodiment of the invention. As shown in FIG. 3, the resistive memory cell of the present invention possesses a pair of gates including the first gate 106a and the second gate 106b formed on the substrate 100. The dielectric layer 202 is located over the substrate 100 and, as shown in FIG. 3, the contact plug 204 penetrates through the dielectric layer 202. Moreover, the bit line 108 is located over the dielectric layer 202 and across the first gate 106a and the second gate 106b.

Between the dielectric layer 202 and the bit line 108, there is a resistive material layer 208 formed on the dielectric layer 202. More specifically, the resistive memory element 110 located right above the contact plug 204 and under the bit line 108, in this embodiment, is a portion of the material layer 208. Therefore, the electrical signal passing between the common doped region 102 and the bit line 108 passes mainly through the resistive memory element 110. The resistivity of the resistive memory element 110 changes in response to the electrical signal and the resistive memory element 110 is used as a variable resistor which can be changed between at least two resistivity values.

The material of the material layer 208 having resistive memory elements 110 can be a metal oxide, a perovskite material, such as a colossal magnetoresistive (CMR) material, or a high temperature superconducting (HTSC) material, such as PrCaMnO₃ (PCMO). In one embodiment, the metal oxide includes hafnium oxide. Also, the metal oxide can be represented by a chemical formula MxOy, wherein M, O, x, y represent transition metal, oxygen, transition composition and oxygen composition respectively. Furthermore, the metal can be, for example but not limited to, aluminum, tantalum, nickel, niobium, chrome, copper, iron, cobalt, hafnium, zirconium or titanium. In addition, there is a conductive layer 210 located between the bit line 108 and the material layer 208. The conductive layer 210 is used as a top electrode of the resistive memory element 110. The material of the top electrode 208 can be, for example but not limited to, iridium, platinum, iridium oxide, titanium nitride, titanium aluminum nitride, ruthenium or ruthenium oxide. In one embodiment, the material of the top electrode 208 can be, for example, polysilicon.

In the present invention, for a single resistive memory cell, two gates having different lengths share one common doped region, which is used as a common drain region, so that the resistive memory cell provided by the present invention is a multi-level cell (MLC) used for storing multi bits according different programming levels. Moreover, by using the resistive memory cell with variable resistances according to different operation levels, the resistive memory cell provided by the present invention can be also adopted to be a multi-level switch or a multi-level selector. Typically, the metal-oxide-semiconductor field effect transistor (MOSFET) with a smaller gate length, such as the second length w2, produces a larger driven current at the same applied voltage than that with a larger gate length, such as the first length w1, does. Therefore, each of the resistive memory cells in the resistive memory array can be driven by three different current levels including the sum of the smaller current and the larger current, the smaller current and the larger current. Under the operations with three current levels respectively, three different resistance states of the resistive memory element are correspondingly produced. Accordingly, the three resistance states of the resistive memory element further combines with the un-programmed state to be a total of four states.

Specifically, when the same gate voltage V1 is applied to both MOSFETs respectively having the first gate 106a and the second gate 106b so that both MOSFETS are turned on, the electrical signal passing through the resistive memory element 110 is in a form of a sum current of the first current passing through the first channel under the first gate and the second current passing through the second channel under the second gate. In response to the electrical signal as a form of the sum current, the resistance of the resistive memory element 110 is switched to a first resistance R1. Alternatively, when the MOSFET with the first gate 106a is switched off and the MOSFET with the second gate 106b is switched on with the voltage V1, the electrical signal passing through the resistive memory element 110 is in a form of only the second transistor's current. In response to the electrical signal, the resistance of the resistive memory element 110 is switched to be a second resistance R2. In addition, when the MOSFET with the first gate 106a is switched on with the gate voltage V1, and the MOSFET with the second gate 106b is switched off, the electrical signal passing through the resistive memory element 110 is in a form of only the first transistor's current. In response to the electrical signal, the resistance of the resistive memory element 110 is switched to be a third resistance R3. Moreover, when the resistive memory cell is at an un-programmed state, the resistance of the resistive memory element is denoted as a fourth resistance R4. Hence, the first resistance, the second resistance, the third resistance and the fourth resistance represent the behaviors of two bits of data respectively.

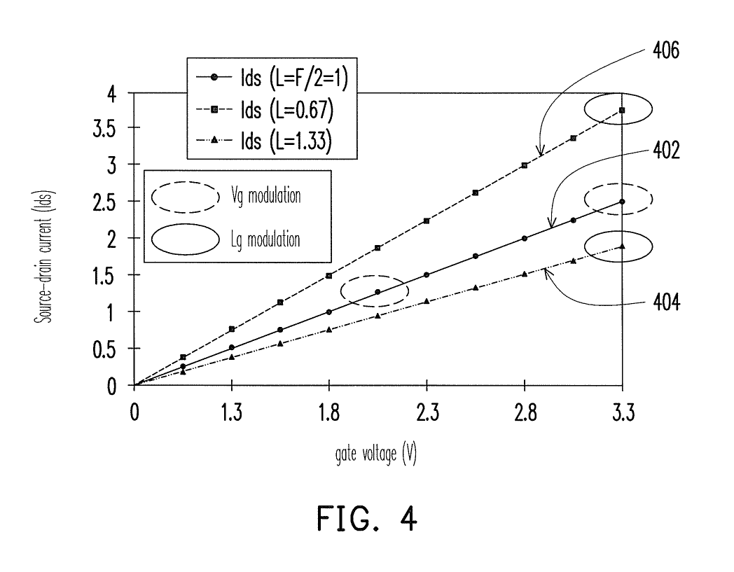

In the present invention, by controlling the lengths of the gates within the same resistive memory cell, the purpose for storing more than one bit data in a limited size of the memory cell can be easily achieved. FIG. 4 is a plot diagram of source-drain current versus gate voltage under linear (triode) operation, showing the differences between the voltage modulation operation of the resistive memory cell and the gate length modulation operation of the resistive memory cell. The circled points indicate the natural choice of maximum and half-maximum currents for each of the two cases. As shown in FIG. 4, for the voltage modulation operation in which the lengths of the gates in the same resistive memory cell are equal to each other, the maximum source-drain current when the voltage is 3.3 V is not as large as for gate length modulation. Apparently, the use of different gate lengths (i.e. gate length modulation operation) is advantageous over the use of different gate voltages (i.e. voltage modulation operation) for the same gate length since the available source-drain current of the gate length modulation is larger. Furthermore, by shrinking the lengths of the gates, the available source-drain current can increase even further. Also, by applying different gate voltages for the different gate lengths, different source-drain voltages or different bit line voltages, additional intermediate storage states can be accessed which increases the bit density.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A resistive memory cell on a substrate, comprising:
a first metal-oxide-semiconductor field effect transistor (MOSFET) and a second MOSFET with a first gate and a second gate respectively, disposed on the substrate, wherein a first length of the first gate is different from a second length of the second gate and the first MOSFET and second MOSFET share a common doped region;
a contact plug electrically connected to the common doped region;
a bit line disposed over the substrate; and
a resistive memory element connected between the contact plug with the bit line.

2. The resistive memory cell of claim 1, wherein a ratio of the first length to the second length is about 1.5-9.

3. The resistive memory cell of claim 1, wherein the first length is about 10-90 nm.

4. The resistive memory cell of claim 1, wherein the second length is about 5-35 nm.

5. The resistive memory cell of claim 1, wherein the resistive memory element material extends along and under the bit line.

6. The resistive memory cell of claim 1, wherein the material of the resistive memory elements includes a metal oxide.

7. A resistive memory array on a substrate, comprising:
a plurality of pairs of MOSFETs on the substrate, wherein each pair of MOSFETs shares a common doped region formed therein and each pair of MOSFETs comprises a first gate and a second gate parallel to each other and a first length of the first gate is different from a second length of the second gate;
a plurality of bit lines disposed over the substrate and across the first gate and the second gate in each pair of MOSFETs; and
a plurality of resistive memory elements located between the bit lines and the common doped regions respectively, wherein each of the bit lines is electrically connected to each of the common doped regions through one of the resistive memory elements.

8. The resistive memory array of claim 7, wherein a ratio of the first length to the second length is about 1.5-9.

9. The resistive memory array of claim 7, wherein the first length is about 10-90 nm.

10. The resistive memory array of claim 7, wherein the second length is about 5-35 nm.

11. The resistive memory array of claim 7, wherein the material of the resistive memory elements includes a metal oxide.

12. The resistive memory array of claim 7, wherein the material of the resistive memory elements is in the form of a line under and along each bit line.
